(19) United States
(12) Patent Application Publication
(10) Pub. No.: US 2017/0125273 A1
(43) Pub. Date: May 4, 2017

(54) WAFER STORAGE AND TRANSPORT DEVICE

(71) Applicant: CHiFF TECHNOLOGY INC., Hsinchu City (TW)

(72) Inventors: Kuo-Hsiang HSU, Hsinchu City (TW); Jen-Lin CHANG, Taoyuan City (TW)

(21) Appl. No.: 14/930,028

(22) Filed: Nov. 2, 2015

(51) Int. Cl. H01L 21/677; H01L 21/673

(52) U.S. Cl. CPC H01L 21/67745; H01L 21/6732

(57) ABSTRACT

A wafer storage and transport device is adapted to store and transport a storage box. The wafer storage and transport device includes a housing, a rotary rack and a transport mechanism. The housing has a transport zone. The rotary rack is rotatable about an axis, and includes a plurality of angularly spaced-apart carrier seats that surround the axis. Each of the carrier seats is rotatable to correspond in position to the transport zone of the housing, and is adapted for the storage box to be disposed co-rotatably thereon. The transport mechanism is for transporting the storage box out of the housing when the storage box is rotated by the rotary rack to correspond in position to the transport zone of the housing.

### FIELD

The disclosure relates to a wafer storage and transport device, and more particularly to a rotary-type wafer storage and transport device that can be disposed adjacent to a processing machine for temporary storage of wafers.

### BACKGROUND

Semiconductor wafer fabrication involves a sequence of processes, and wafer fabrication facilities are usually designed to have several wafer storage and shelving devices. Each of the wafer storage and shelving devices is disposed adjacent to a processing machine, and is for temporary storage of wafers that have been processed or are about to be processed. To be more specific, the wafers are received in wafer storage boxes that are disposed in the wafer storage and shelving devices for subsequent processing by the processing machine or for transport to another processing area.

A conventional wafer storage and shelving device includes a plurality of platforms that are arranged in a matrix and that are configured for the wafers to be disposed thereon. Adjacent ones of the platforms define a passage therebetween for allowing a robotic arm to transport the wafer storage boxes onto a selected one of the platforms along a pre-determined path. However, since the platforms are stationary, the wafer storage and shelving device needs to be configured to have a sufficient number of passages for transport of the wafer storage boxes, thus undesirably increasing the overall size of the wafer storage and shelving device. In addition, since desired or required fabrication processes may be different for different product specifications, the number of the wafers stored in the wafer storage and shelving device may change accordingly. Therefore, a wafer storage device that is convenient to use is in demand.

### SUMMARY

Therefore, an object of the disclosure is to provide a wafer storage and transport device that can alleviate at least one of the drawbacks of the prior arts.

According to the disclosure, the wafer storage and transport device is adapted to store and transport at least one storage box that receives a plurality of wafers therein. The wafer storage and transport device includes a housing, a rotary rack and a transport mechanism. The housing has a transport zone. The rotary rack is disposed in the housing, is rotatable about an axis, and includes a plurality of angularly spaced-apart carrier seats that surround the axis. Each of the carrier seats is rotatable to correspond in position to the transport zone of the housing, and is adapted for the storage box to be disposed co-rotatably thereon. The transport mechanism is for transporting the storage box out of the housing when the storage box is rotated by the rotary rack to correspond in position to the transport zone of the housing.

### BRIEF DESCRIPTION OF THE DRAWINGS

Other features and advantages of the disclosure will become apparent in the following detailed description of the embodiment with reference to the accompanying drawings, of which:

FIG. 1 is a partly exploded perspective view, illustrating an embodiment of a wafer storage and transport device according to the disclosure, two storage boxes to be disposed therein, and a processing machine;

FIG. 2 is a fragmentary perspective view illustrating the embodiment and the processing machine, in which a first side wall of a housing of the embodiment is omitted;

FIG. 3 is a front view illustrating the embodiment and the processing machine, in which the first side wall of the housing is omitted; and

FIGS. 4A to 4I are schematic diagrams illustrating how the embodiment is operated.

### DETAILED DESCRIPTION

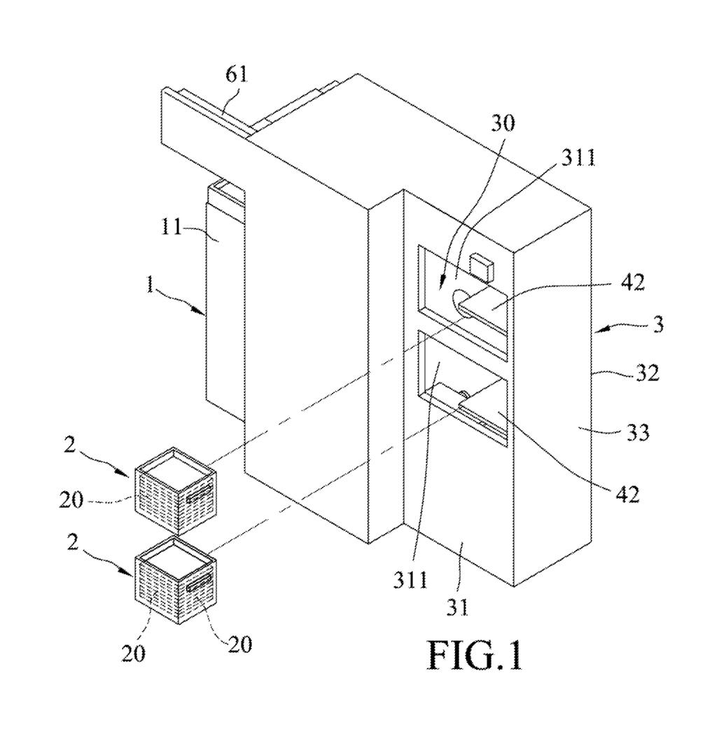

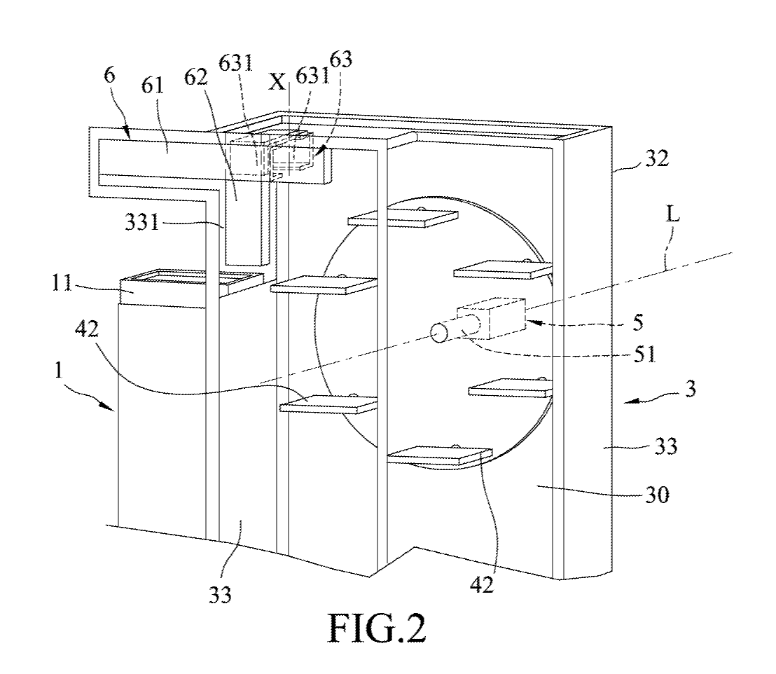

Referring to FIGS. 1 to 3, an embodiment of a wafer storage and transport device according to the disclosure is adapted to store and transport a plurality of storage boxes 2 that receive a plurality of wafers 20 therein, and is adapted to be disposed adjacent to a processing machine 1 that has a processing zone 11. The wafer storage and transport device is shown to include a housing 3, a rotary rack 4, a driving mechanism 5 and a transport mechanism 6.

The housing 3 includes a vertical first side wall 31, a vertical second side wall 32 that is spaced apart from the first side wall 31, and two opposite lateral side walls 33 that interconnect the first and second side walls 31, 32, and that cooperate with the first and second side walls 31, 32 to define an accommodating space 30 that accommodates the rotary rack 4. The first side wall 31 is formed with two open windows 311 through which the storage boxes 2 are put into or removed from the accommodating space 30. Alternatively, in other variations of the embodiment, the number of the open windows 311 may be one, three, etc. depending on actual requirement.

One of the lateral side walls 33 of the housing 3 has a transport zone 331 that is disposed adjacent to the processing zone 11 of the processing machine 1. The transport zone 331 is configured as an opening and spatially communicates with the accommodating space 30.

The rotary rack 4 is rotatably disposed in the housing 3, and includes a vertical wall 41 and a plurality of carrier seats 42. The vertical wall 41 is configured as a circular plate, is rotatably mounted on the second side wall 32 of the housing 3, and is rotatable about a horizontal axis (L) that extends through the center of the vertical wall 41. The carrier seats 42 surround the horizontal axis (L), are angularly equidistant, and extend from a side surface of the vertical wall 41 in a direction toward the first side wall 31. Each of the carrier seats 42 of the rotary rack 4 is rotatable to correspond in position to either one of the open windows 311, and is adapted for one of the storage boxes 2 to be disposed co-rotatably thereon. Each of the carrier seats 42 is rotatable to correspond in position to the transport zone 331 of the housing 3. In the embodiment, the number of the carrier seats 42 is six. It should be noted that the carrier seats 42 are angularly equidistant such that the weight of the carrier seats 42 are evenly distributed, thereby ensuring continuous and balanced rotation of the rotary rack 4. In other variations of the embodiment, the number of the carrier seats 42 may vary depending on design needs.

The driving mechanism 5 is connected to the vertical wall 41 of the rotary rack 4 for driving rotational movement of the rotary rack 4 about the horizontal axis (L). The driving mechanism 5 includes a motor 50, and a driving shaft 51 that extends along the horizontal axis (L), that is substantially perpendicular to the vertical wall 41 of the rotary rack 4, and that is driven by the motor 50 to drive rotation of the vertical wall 41. Alternatively, in other variations of the embodiment, the driving mechanism 5 may be configured as, for example but not limited to, gears, or a pulley and belt system as long as the driving mechanism 5 can drive rotation of the vertical wall 41 about the horizontal axis (L).

The transport mechanism 6 is disposed adjacent to the transport zone 331 of the housing 3, and is for transporting the storage boxes 2 out of the housing 3 one at a time. The transport mechanism 6 includes a horizontal rail 61, a vertical rail 62 and a mechanical arm 63. The horizontal rail 61 is securely connected to the housing 3, and extends from the accommodating space 30 outwardly through the transport zone 331 along a left-right direction such that a portion of the horizontal rail 61 is at a position corresponding to the processing zone 11 of the processing machine 1. The vertical rail 62 extends along a top-bottom direction, is connected to the horizontal rail 61, and is slidable back and forth along the horizontal rail 61. The mechanical arm 63 is connected to the vertical rail 62, is slidable along the vertical rail 62, and is adapted for transporting the storage boxes 2 into or out of the transport zone 331. The mechanical arm 63 is slidable back and forth along the horizontal rail 61 together with the vertical rail 62. The mechanical arm 63 is rotatable about a vertical axis (X), and includes two spaced-apart clamp portions 631. The clamp portions 631 are driven by a control device (not shown) to move toward or away from each other for picking up or dropping off one of the storage boxes 2. Since the structure of the mechanical arm 63 and the technique for driving the mechanical arm 63 to move along the vertical rail 62 should be readily appreciated by those skilled in the art, further details are not provided herein for the sake of brevity.

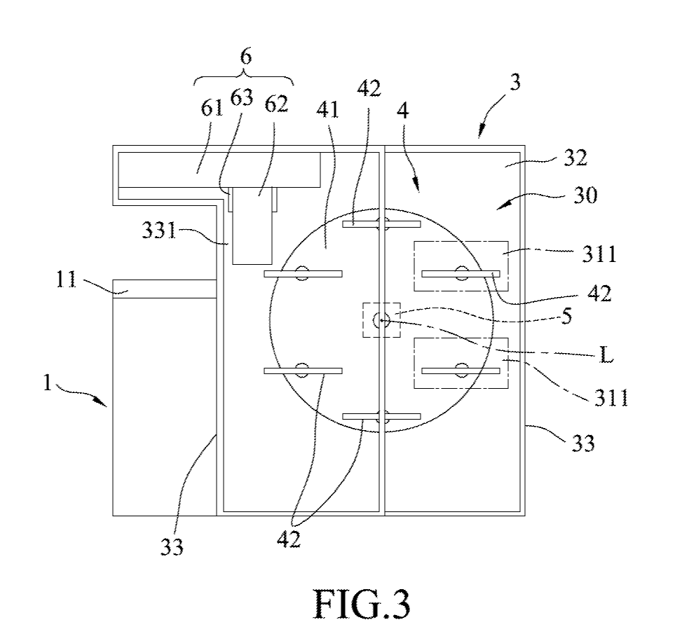

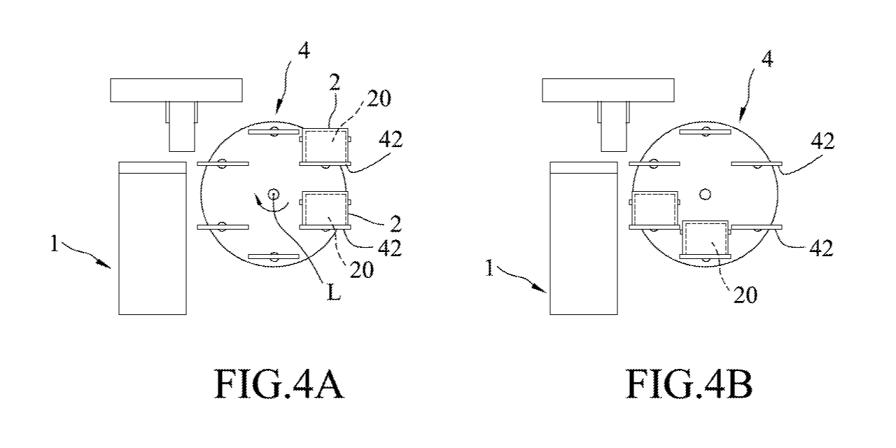

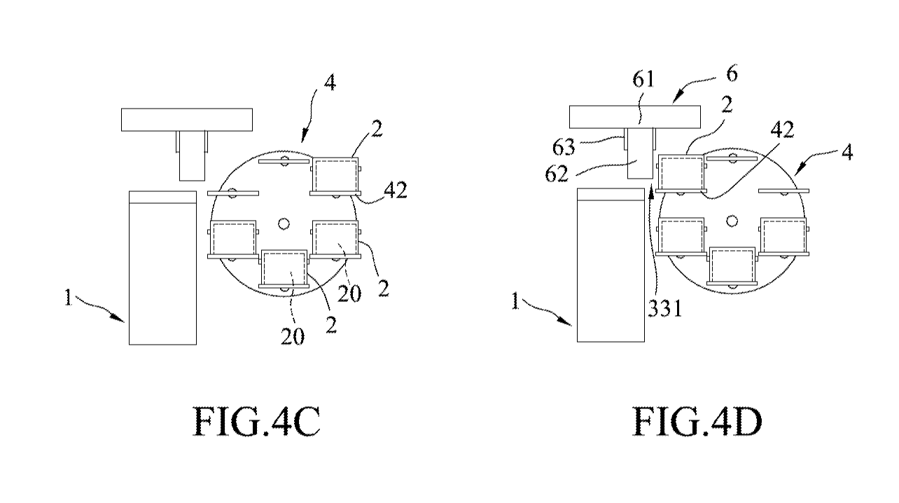

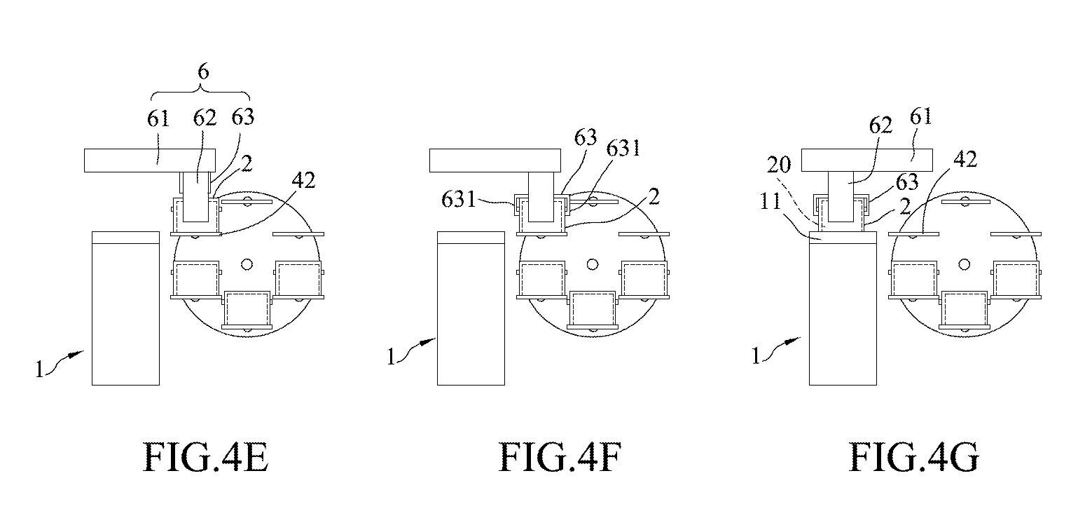

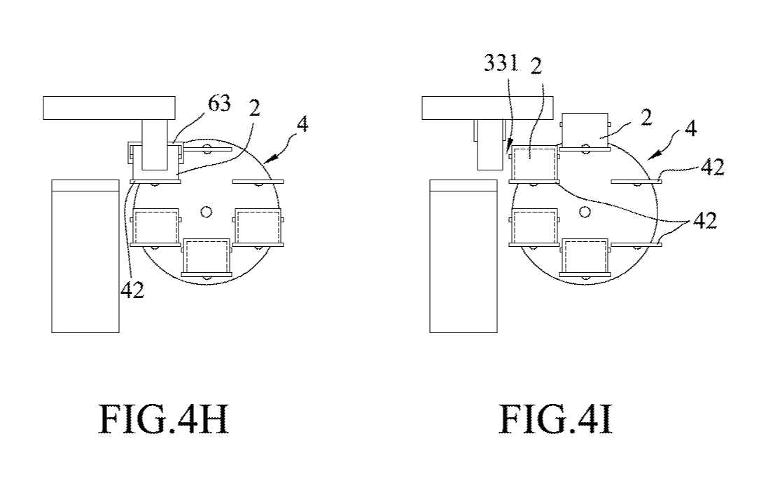

Referring to FIGS. 3 to 4, when in use, the rotary rack 4 is rotated until two adjacent carrier seats 42 are respectively aligned with the open windows 311 of the housing 3, and two of the storage boxes 2 are loaded respectively onto the two adjacent carrier seats 42 (see FIG. 4A) through the open windows 311 by a loading mechanism (not shown). Subsequently, the rotary rack 4 is rotated by the driving mechanism 5 until another two adjacent carrier seats 42 are respectively aligned with the open windows 311 for loading of another two of the storage boxes 2 thereon (see FIGS. 4B and 4C), so that the wafers 20 in the storage boxes 2 are temporarily stored.

When the storage boxes 2 need to be transported individually to the processing machine 1 for processing, the rotary rack 4 is driven to rotate until one of the storage boxes 2 is positioned adjacent to the transport zone 331 (see FIG. 4D). At this time, the vertical rail 62 of the transport mechanism 6 is driven by the control device to move toward the one of the storage boxes 2. When the mechanical arm 63 of the transport mechanism 6 is moved to a position directly located above the one of the storage boxes 2 (see FIG. 4E), the mechanical arm 63 is rotated by 90 degrees about the vertical axis (X), and then is moved downwardly along the vertical rail 62 to pick up the one of the storage boxes 2 (see FIG. 4F). Subsequently, the mechanical arm 63 is moved upwardly along the vertical rail 62, and then is moved together with the vertical rail 62 along the horizontal rail 61 to transport the one of the storage boxes 2 out of the housing 3. When the one of the storage boxes 2 is moved to a position directly located above the processing zone 11, the mechanical arm 63 then is moved downwardly to drop off the one of the storage boxes 2 (see FIG. 4G) onto the processing zone 11 of the processing machine 1. At this time, the wafers 20 in the one of the storage boxes 2 can be taken out and transported into the processing machine 1 using a transfer tool (not shown). Since operations of the transfer tool are not features of this disclosure, details of the same are not be provided herein for the sake of brevity.

After the wafers are transported into the processing machine 1, the one of the storage boxes 2 is transported back into the housing 3 by the mechanical arm 63 (see FIG. 4H). The rotary rack 4 is then rotated for the transport of the next one of the storage boxes 2 (see FIG. 4I).

During the process of transporting any one of the storage boxes 2 through the transport zone 331, unloading of the one of the storage boxes 2 with the wafers 20 taken out and loading of another one of the storage boxes 2 may be carried out simultaneously. It should be noted that the above-mentioned sequence of storage and transport of the storage boxes 2 is just an example to demonstrate how the wafer storage and transport device is operated, and should not limit the sequence of operations in actual practice.

It is further noted that each of the carrier seats 42 maybe kept level in a known manner, e.g., by a ratchet device and a step motor. Moreover, the wafer storage and transport device of this disclosure may include a plurality of position sensors for detecting if the carrier seats 42 are positioned accurately.

To sum up, since the rotary rack 4 is configured to be rotatable, each of the carrier seats 42 is rotatable to correspond in position to either one of the open windows 311 for loading and/or unloading of either one of the storage boxes 2, and is rotatable to correspond in position to the transport zone 331 for convenient transport of the storage boxes 2 into or out of the housing 3. The wafer storage and transport device in this disclosure occupies a relatively small space as compared to the above-mentioned prior art, and allows for flexible and convenient operations since loading, unloading and transport operations may be carried out simultaneously and continuously. The wafer storage and transport device in this disclosure can be used in the semiconductor industry or other related industry for convenient storage and transport of wafers.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A wafer storage and transport device adapted to store and transport at least one storage box that receives a plurality of wafers therein, the wafer storage and transport device comprising:
a housing having a transport zone;
a rotary rack disposed in said housing, rotatable about an axis, and including a plurality of angularly spaced-apart carrier seats that surround the axis, each of said carrier seats being rotatable to correspond in position to said transport zone of said housing, and being adapted for the storage box to be disposed co-rotatably thereon.

2. The wafer storage and transport device as claimed in claim. 1, further comprising a transport mechanism for transporting the storage box out of said housing when the storage box is rotated by said rotary rack to correspond in position to said transport zone of said housing.

3. The wafer storage and transport device as claimed in claim 1, wherein:
said housing defines an accommodating space that accommodates said rotary rack and that is in spatial communication with said transport zone, said housing being formed with at least one open window through which the storage box is put into or removed from said accommodating space; and
each of said carrier seats of said rotary rack is rotatable to correspond in position to said at least one open window.

4. The wafer storage and transport device as claimed in claim 3, wherein said housing further includes
a first side wall that is formed with said at least one open window,
a second side wall that is spaced apart from said first side wall, and
two opposite lateral side walls that interconnect said first side wall and said second side wall, and that cooperate with said first side wall and said second side wall to define said accommodating space, one of said lateral side walls having said transport zone.

5. The wafer storage and transport device as claimed in claim 4, wherein said transport zone is configured as an opening that is in spatial communication with said accommodating space.

6. The wafer storage and transport device as claimed in claim 4, wherein said rotary rack further includes a vertical wall that is rotatably mounted on said second side wall and that is rotatable about the axis, said carrier seats extending from a side surface of said vertical wall in a direction toward said first side wall.

7. The wafer storage and transport device as claimed in claim 3, wherein said transport zone is configured as an opening that is in spatial communication with said accommodating space.

8. The wafer storage and transport device as claimed in claim 2, wherein said transport mechanism includes a horizontal rail, a vertical rail that is connected to said horizontal rail and that is slidable along said horizontal rail, and a mechanical arm that is slidable along said vertical rail and that is adapted for transporting the storage box into or out of said transport zone.

9. The wafer storage and transport device as claimed in claim 8, wherein said horizontal rail of said transport mechanism is securely connected to said housing.

10. The wafer storage and transport device as claimed in claim 2, wherein said transport mechanism is disposed adjacent to said transport zone of said housing.

11. The wafer storage and transport device as claimed in claim 1, further comprising a driving mechanism connected to said rotary rack for driving rotational movement of said rotary rack.

12. The wafer storage and transport device as claimed in claim 3, further comprising a driving mechanism connected to said rotary rack for driving rotational movement of said rotary rack.

13. The wafer storage and transport device as claimed in claim 4, further comprising a driving mechanism connected to said rotary rack for driving rotational movement of said rotary rack.

14. The wafer storage and transport device as claimed in claim 5, further comprising a driving mechanism connected to said rotary rack for driving rotational movement of said rotary rack.

15. The wafer storage and transport device as claimed in claim 6, further comprising a driving mechanism connected to said rotary rack for driving rotational movement of said rotary rack.

16. The wafer storage and transport device as claimed in claim 7, further comprising a driving mechanism connected to said rotary rack for driving rotational movement of said rotary rack.

17. The wafer storage and transport device as claimed in claim 16, wherein said driving mechanism includes a driving shaft that extends along the axis and that is substantially perpendicular to said base.
